(19) United States
(12) Patent Application Publication
(10) Pub. No.: US 2024/0186781 A1
(43) Pub. Date: Jun. 6, 2024

(54) ELECTRICAL JUNCTION BOX

(71) Applicant: SUMITOMO WIRING SYSTEMS, LTD., Mie (JP)

(72) Inventor: Shunsuke KATSUSE, Mie (JP)

(21) Appl. No.: 18/285,599

(22) PCT Filed: Mar. 17, 2022
(86) PCT No.: PCT/JP2022/012352

§ 371 Date: Oct. 4, 2023

(30) Foreign Application Priority Data
Apr. 9, 2021 (JP) 2021-066186

(51) Int. Cl. H02G 3/16; H05K 7/20

(52) U.S. Cl. CPC H02G 3/16; H05K 7/20154

(57) ABSTRACT

Size is reduced. An electrical junction box (A) includes: a base member (10) to which electric components (13) are to be attached; and a pair of side-wall members (11) that are attached to the base member (10) so as to sandwich the base member (10) in a width direction, wherein a component housing chamber (12) for housing the electric components (13) is formed by the base member (10) and the pair of side-wall members (11), the base member (10) includes projections (22) that project toward the width direction from outer side surfaces of the base member (10), and the side-wall members (11) have formed therein housing recesses (46) for housing the projections (22).

### TECHNICAL FIELD

The present disclosure relates to an electrical junction box.

### BACKGROUND

Patent Document 1 discloses a technique for attaching interruption elements to the inside of an interruption-element housing portion formed in a junction-box main body. The interruption-element housing portion includes a space that is open in the upper surface of the junction-box main body, and the interruption elements are fitted into the interruption-element housing portion from above the junction-box main body.

### PRIOR ART DOCUMENT

### Patent Document

Patent Document 1: JP 2021-002441 A

### SUMMARY OF THE INVENTION

### Problems to be Solved

In the above-described structure, a circumferential wall portion of the interruption-element housing portion surrounds the electric components from the front-rear and left-right directions. Thus, there is a concern that the fingers used to pinch an interruption element may interfere with the circumferential wall portion when the interruption element is pinched with fingers and attached to the interruption-element housing portion. As a countermeasure against this, it is conceivable to form side-wall portions of the junction-box main body covering the side surfaces of the interruption-element housing portion as separate components. This would allow the interruption elements to be housed inside the interruption-element housing portion without a worker's fingers interfering with side-wall members. The interruption elements can be protected by attaching the side-wall members to a base member after the interruption elements have been housed in the interruption-element housing portion. However, if the side surfaces of the interruption-element housing portion are covered with side-wall portions, the width-direction dimension would increase because an outer wall portion of the interruption-element housing portion and an outer wall portion of a side-wall portion would overlap in the width direction.

An electrical junction box according to the present disclosure has been made based on the above-described circumstances, and aims to reduce size.

### Means to Solve the Problem

An electrical junction box according to the present disclosure includes:
a base member to which electric components are to be attached; and
a pair of side-wall members that are attached to the base member so as to sandwich the base member in a width direction,
wherein a component housing chamber for housing the electric components is formed by the base member and the pair of side-wall members,
the base member includes projections that project toward the width direction from outer side surfaces of the base member, and
the side-wall members have formed therein housing recesses for housing the projections.

### Effect of the Invention

According to the present disclosure, size can be reduced.

### BRIEF DESCRIPTION OF THE DRAWINGS

FIG. 1 is a perspective view of an electrical junction box according to embodiment 1.

FIG. 2 is a perspective view illustrating a state in which the electrical junction box has been separated into a base member and side-wall members.

FIG. 3 is a perspective view of the base member.

FIG. 4 is a bottom view of the electrical junction box.

FIG. 5 is a cross-sectional front view of the electrical junction box.

FIG. 6 is a perspective view illustrating a state in which a side-wall member has been separated into a side-wall main body and a busbar.

### DETAILED DESCRIPTION TO EXECUTE THE INVENTION

### Description of Embodiments of Present Disclosure

First, aspects of embodiment of the present disclosure will be listed and described.
(1) The electrical junction box according to the present disclosure includes: a base member to which electric components are to be attached: and a pair of side-wall members that are attached to the base member so as to sandwich the base member in a width direction, wherein a component housing chamber for housing the electric components is formed by the base member and the pair of side-wall members, the base member includes projections that project toward the width direction from outer side surfaces of the base member, and the side-wall members have formed therein housing recesses for housing the projections. According to the configuration of the present disclosure, size can be reduced because the width dimension decreases by an amount corresponding to the projecting dimensions of the projections as a result of the projections being housed inside the housing recesses.
(2) Preferably, busbars are housed inside the side-wall members, and, in a state in which the base member and the side-wall members are separated from one another, the housing recesses are open so as to expose parts of the busbars. According to this configuration, size can be reduced in the width direction because there are no partition walls between the projections and the busbars.
(3) Preferably, in (2), the busbars each include a substrate portion and a heat-dissipating plate portion that is disposed so as to overlap the substrate portion, the heat-dissipating plate portions are disposed so as to face the housing recesses, and heat-dissipation spaces are formed between the base member and the side-wall members. According to this configuration, heat from the heat-dissipating plate portions can be discharged to the heat-dissipation spaces via the housing recesses.
(4) Preferably, the base member has provided therein separation-restricting portions that restrict the side-wall members from separating from the base member in the width direction. According to this configuration, even if the side-wall members are urged to undergo deformation so as to separate from the base member, the deformation is prevented by the separation-restricting portions. Thus, an increase in width dimension due to the deformation of the side-wall members can be prevented.
(5) Preferably, in (4), the outer surfaces of the side-wall members include outermost regions that are farthest from the base member in the width direction, and the separation-restricting portions are disposed only in regions that are closer to the base member than the outermost regions are. According to this configuration, an increase in width dimension due to the presence of the separation-restricting portions can be prevented.

### DETAILS OF EMBODIMENTS OF PRESENT DISCLOSURE

### Embodiment 1

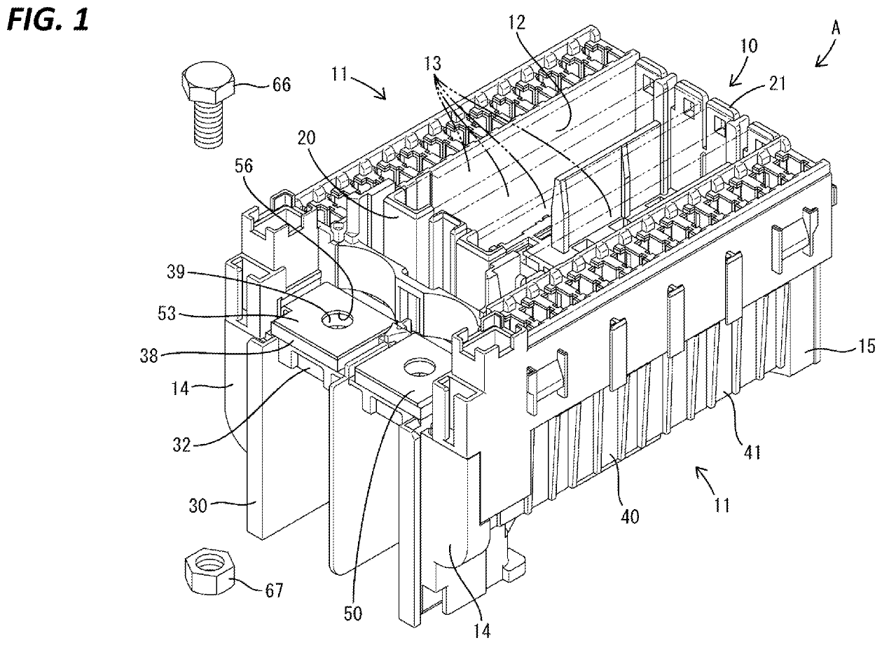

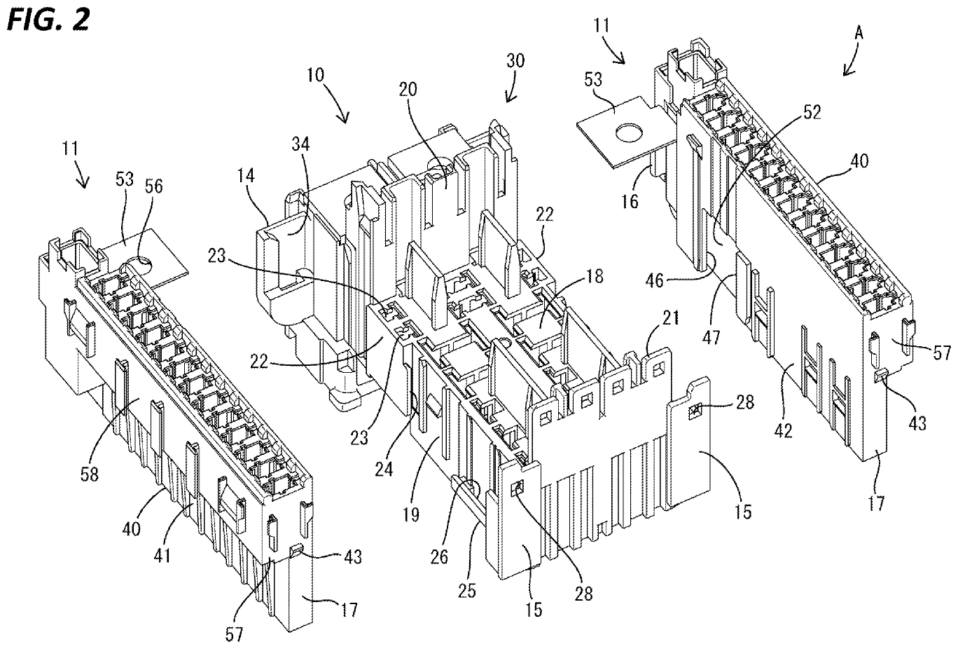

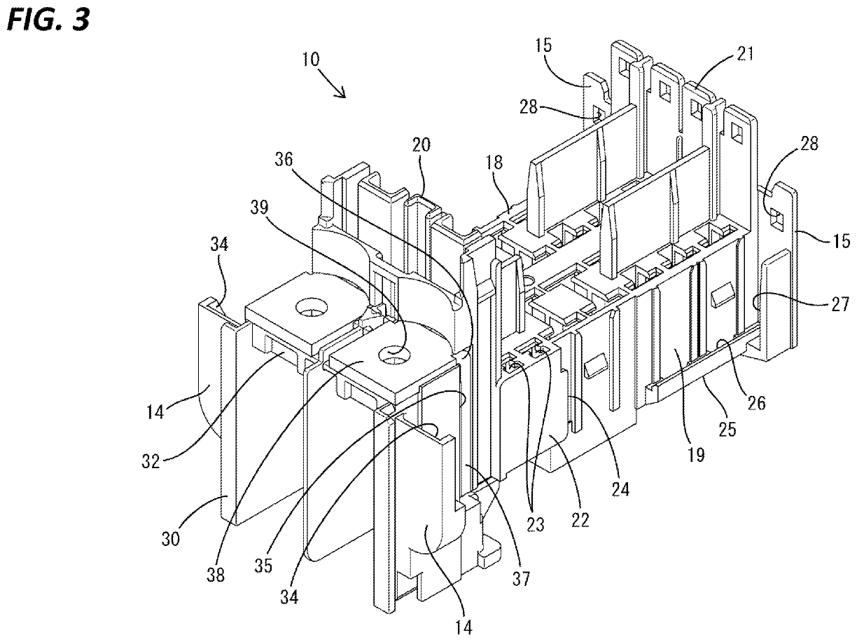

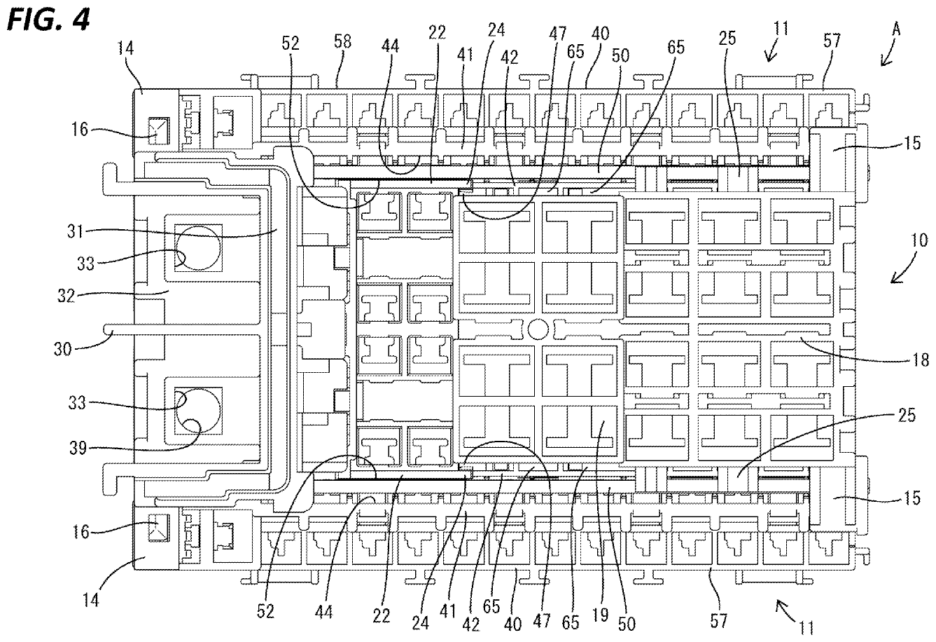

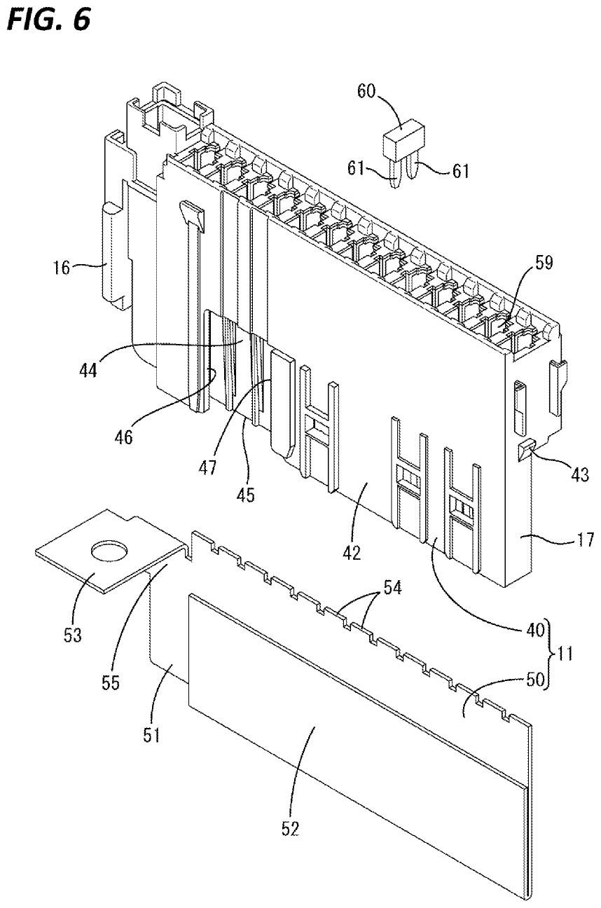

Embodiment 1 that is a specific example of the electrical junction box according to the present disclosure will be described with reference to FIGS. 1 to 6. Note that the present invention is not limited to these examples but defined by the claims, and is intended to include all modifications that are within the meaning and scope of equivalents of the claims. In present embodiment 1, in regard to the front and rear directions, the diagonal lower left side in FIGS. 1 and 3, the diagonal upper left side in FIGS. 2 and 6, and the left side in FIG. 4 are defined as the front side. In regard to the upper and lower directions, the directions in FIGS. 1 to 3 and FIGS. 5 and 6 are defined, as-is, as the upper and lower sides. In regard to the left and right directions, the directions in FIG. 4 are defined, as-is, as the left and right sides. The expressions “left-right direction” and “width direction” are used synonymously.

### Overview of Electrical Junction Box A

As illustrated in FIGS. 1 and 2, the electrical junction box A according to present embodiment 1 is formed by attaching, to one another, one base member 10 and a bilaterally symmetrical pair of side-wall members 11 that are separate members from the base member 10. The pair of side-wall members 11 are attached to the base member 10 so as to sandwich the base member 10 from the left and right sides, or in other words, to sandwich the base member 10 in the width direction. The electrical junction box A includes a component housing chamber 12 that is defined by the base member 10 and the pair of side-wall members 11. The component housing chamber 12 is open in the upper surface of the electrical junction box A. The component housing chamber 12 is configured such that a plurality of electric components 13, such as fusible links, can be housed inside the component housing chamber 12.

A pair of left and right front-side fitting portions 14 are formed in the front end portion of the base member 10, and a pair of left and right rear-side fitting portions 15 are formed in the rear end portion of the base member 10. As illustrated in FIGS. 2 and 6, a pair of left and right front-side insertion portions 16 are formed in the front end portions of the side-wall members 11, and a pair of left and right rear-side insertion portions 17 are formed in the rear end portions of the side-wall members 11. The base member 10 and the side-wall members 11 are held in an attached state as a result of the front-side fitting portions 14 and the front-side insertion portions 16 being fit to one another, and the rear-side fitting portions 15 and the rear-side insertion portions 17 being fit to one another.

### Base Member 10

The base member 10 includes a holding member 18 made from synthetic resin, a terminal block 30 that is made from synthetic resin and that is a separate component from the holding member 18, and a bilaterally symmetrical pair of metal plates 36. As illustrated in FIGS. 2 and 3, the holding member 18 is a single component including a cuboid-shaped main body portion 19 whose long sides are oriented in the front-rear direction, a front plate portion 20 that extends upward from the front end edge of the main body portion 19, and a rear plate portion 21 that extends upward from the rear end edge of the main body portion 19. The space surrounded by the upper surface of the main body portion 19, the rear surface of the front plate portion 20, and the front surface of the rear plate portion 21 functions as the component housing chamber 12. In a state in which the side-wall members 11 are not attached to the base member 10, the component housing chamber 12 is open to the outside of the base member 10 in the upper surface of the base member 10 and the left and right side surfaces of the base member 10.

Bilaterally symmetrical projections 22 are formed in the front end portions of the left and right outer side surfaces of the main body portion 19. The projections 22 are parts that form outermost-position cavities 23 that are disposed along the outer side surfaces of the main body portion 19 in the width direction, among a plurality of cavities formed inside the main body portion 19. In a side view in which the base member 10 is seen sideways, the projections 22 have a rectangular shape. The projections 22 constitute the outer side surfaces of the main body portion 19, and have the function as partition walls that partition the outermost-position cavities 23 and the space outside the main body portion 19 from one another. The projections 22 project outward in the width direction in the shape of a step, relative to regions of the outer side surfaces of the main body portion 19 other than the projections 22. Guide ribs 24 extending in the up-down direction are formed in the rear edge portions of the projections 22. The width-direction regions in which the guide ribs 24 are formed are limited to within the ranges in which the projections 22 are formed in the directions in which the projections 22 project toward the width direction.

As illustrated in FIGS. 2 to 5, a bilaterally symmetrical pair of extending portions 25 are formed in the rear end portions of the left and right outer side surfaces of the main body portion 19. The extending portions 25 extend in the front-rear direction along the lower end edges of the main body portion 19, and project outward in the left-right direction from the lower end edges of the main body portion 19. As illustrated in FIGS. 2, 3, and 5, hook portions 26 that project upward in the shape of ribs are formed in projecting end edges of the extending portions 25 that extend in the front-rear direction. The hook portions 26 are positioned rearward of the projections 22.

As illustrated in FIG. 3, the bilaterally symmetrical pair of rear-side fitting portions 15 are formed in the left and right end portions of the rear plate portion 21. Guide grooves 27 that are open in the front and upper surfaces of the rear-side fitting portions 15 and that extend in the up-down direction are formed in the rear-side fitting portions 15. Lock holes 28 that place the guide grooves 27 and the rear surfaces of the rear-side fitting portions 15 in communication with one another are formed in the rear-side fitting portions 15.

The terminal block 30 is a single component including supporting plate portions 31 (see FIG. 4) whose plate-thickness directions are oriented in the front-rear direction, and receiving plate portions 32 whose plate-thickness directions are oriented in the up-down direction. Bolt holes 33 (see FIG. 4) that pass through the receiving plate portions 32 in the up-down direction are formed in the receiving plate portions 32. The terminal block 30 is attached to the holding member 18 in a state in which the terminal block 30 covers the front surface of the main body portion 19 and the front surface of the front plate portion 20. The bilaterally symmetrical pair of front-side fitting portions 14 are formed in the left and right end portions of the terminal block 30. As illustrated in FIGS. 2 and 3, groove portions 34 that are open in the upper surface of the terminal block 30 and that extend in the up-down direction are formed in the rear surfaces of the front-side fitting portions 14. As illustrated in FIG. 3, a pair of left and right housing spaces 35 are formed between the front plate portion 20 of the holding member 18 and the supporting plate portions 31 of the terminal block 30. The upper end portions of the housing spaces 35 are open in the shape of left-right-direction slits toward the front of the base member 10.

Each plate 36 is a single component formed by bending a thin metal plate material. As illustrated in FIG. 3, each plate 36 includes a plate-shaped power supply portion 37 that has the shape of a flat plate whose plate-thickness direction is oriented in the front-rear direction, and a plate-shaped mounting portion 38 that extends horizontally toward the front from the upper end edge of the plate-shaped power supply portion 37. A mounting hole 39 that passes through the plate-shaped mounting portion 38 in the up-down direction is formed in the plate-shaped mounting portion 38. The plates 36 are attached to the base member 10 in a state in which the plate-shaped power supply portions 37 thereof are housed inside the housing spaces 35, and the plate-shaped mounting portions 38 thereof are mounted on the receiving plate portions 32. Power-supply terminals (unillustrated) connected to a battery (unillustrated) can be connected to the plate-shaped power supply portions 37.

### Side-Wall Members 11

Each side-wall member 11 is formed by attaching a side-wall main body 40 made from synthetic resin and a busbar 50 made from metal to one another. As illustrated in FIGS. 2 and 6, the side-wall main body 40 is a single component which has a shape that is long in the front-rear direction in a plan view, and whose wall-thickness direction is oriented in the left-right direction. As illustrated in FIG. 2 and FIGS. 4 to 6, the side-wall main body 40 includes an outer wall portion 41 whose wall-thickness direction is oriented in the left-right direction, and an inner wall portion 42 whose wall-thickness direction is oriented in the left-right direction. The lower-end-side part of the front end edge portion of the side-wall main body 40 functions as a front-side insertion portion 16. The lower-end-side part of the rear end edge portion of the side-wall main body 40 functions as a rear-side insertion portion 17. As illustrated in FIGS. 2 and 6, a lock portion 43 that has the shape of a protrusion is formed on the rear end surface of the side-wall main body 40.

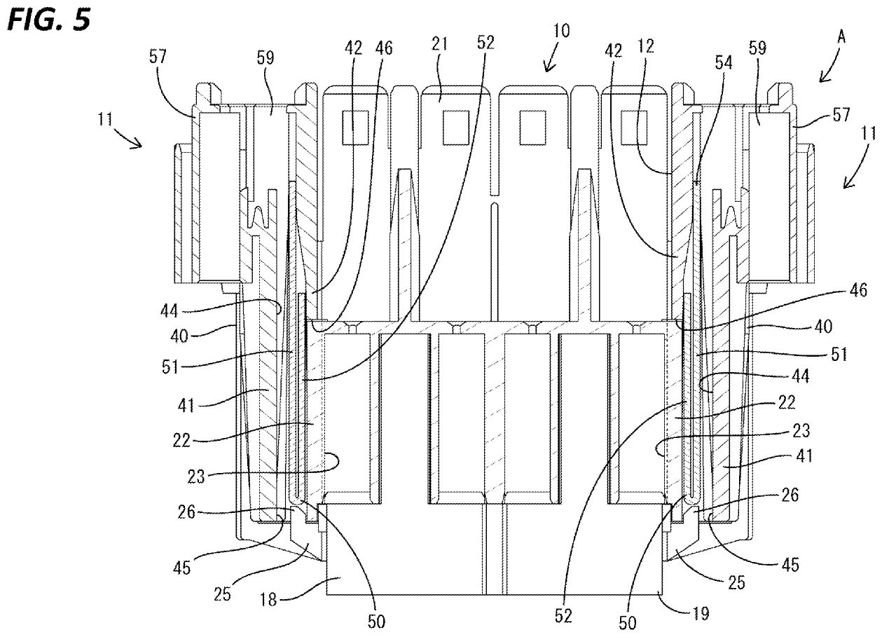

As illustrated in FIGS. 4 and 5, one busbar housing chamber 44 that is sandwiched by the outer wall portion 41 and the inner wall portion 42 is formed inside the side-wall main body 40. The busbar housing chamber 44 is a narrow space that has a left-right dimension smaller than the front-rear and up-down dimensions. As illustrated in FIG. 5, a busbar attachment port 45 that is open in the shape of a front-rear-direction slit is formed in the lower surface of the side-wall main body 40. The busbar attachment port 45 is an opening for attaching the busbar 50 to the busbar housing chamber 44.

As illustrated in FIGS. 2 and 6, a housing recess 46 is formed in the lower-end-side region of the inner wall portion 42, or specifically, in a region that is at the same height as the main body portion 19 of the base member 10. The housing recess 46 is formed in the front end portion of the inner wall portion 42. The housing recess 46 is open in the lower end edge of the inner wall portion 42, and is open in the outer and inner surfaces of the inner wall portion 42. The housing recess 46 places the busbar housing chamber 44 in communication with the outside of the side-wall main body 40. As illustrated in FIGS. 4 and 6, a guide rail 47 that extends in the up-down direction is formed in the rear edge portion of the opening edge of the housing recess 46. The width-direction region in which the guide rail 47 is formed is limited to within the range of the wall-thickness of the inner wall portion 42.

The busbar 50 is a single component that is formed from a metal flat plate that has been punched out in a predetermined shape and bent. As illustrated in FIG. 6, the busbar 50 includes one substrate portion 51, one heat-dissipating plate portion 52, one connection plate portion 53, and a plurality of tabs 54. The substrate portion 51 and the heat-dissipating plate portion 52 each have the shape of a rectangular flat plate whose plate-thickness direction is oriented in the left-right direction. The heat-dissipating plate portion 52 extends from the lower end edge of the substrate portion 51 so as to overlap with the inner surface of the substrate portion 51. The plurality of tabs 54 project upward from the upper end edge of the substrate portion 51, and are disposed so as to be arranged in the front-rear direction with spaces therebetween. The connection plate portion 53 extends horizontally inward from the upper end edge of a supporting portion 55 in the front end portion of the substrate portion 51. A through-hole 56 that passes through the connection plate portion 53 in the up-down direction is formed in the connection plate portion 53.

The busbar 50 is attached to the side-wall main body 40 in a state in which the substrate portion 51, the heat-dissipating plate portion 52, and the tabs 54 are housed inside the busbar housing chamber 44 from the busbar attachment port 45. The connection plate portion 53 projects to the outside of the side-wall main body 40, and projects further inward than the side-wall main body 40 in the width direction, or in other words, toward the base member 10-side.

As illustrated in FIGS. 2 and 6, a wide enlarged-width portion 57 is formed in the upper end portion of the side-wall main body 40. The region of the outer side surface of the side-wall member 11 in which the enlarged-width portion 57 is formed is defined as an outermost region 58 that is positioned outermost in the left-right direction in the outer side surface of the side-wall member 11. In the enlarged-width portion 57, a plurality of fuse housing chambers 59 open in the upper surface of the side-wall main body 40 are disposed so as to be arranged in a single line in the front-rear direction. The lower end portions of the plurality of fuse housing chambers 59 are in communication with the busbar housing chamber 44. Fuses 60 (see FIG. 6) are attached to the fuse housing chambers 59 from above the side-wall member 11. One of the two leads 61 of each fuse 60 is connected to a tab 54 of the busbar 50. Inside the lower-end-side region of the enlarged-width portion 57, harness terminals (unillustrated) that are connected to electric wires (unillustrated) are housed. The harness terminals are connected to the other leads 61 of the fuses 60.

### Assembly Procedure of Electrical Junction Box A

Upon assembling the electrical junction box A, the terminal block 30 is made to temporarily hold the plates 36 in a state in which the holding member 18 and the terminal block 30 are separated from one another, and attachment of the terminal block 30 and the plates 36 is performed. By attaching the terminal block 30 to the holding member 18, the housing spaces 35 are formed and the plate-shaped power supply portions 37 of the plates 36 are housed inside the housing spaces 35, and the assembly of the base member 10 is complete. The plate-shaped mounting portions 38 are mounted on the receiving plate portions 32.

After assembling the base member 10, the electric components 13 are attached to the holding member 18 such that the electric components 13 are housed inside the component housing chamber 12 from above the base member 10. Because the component housing chamber 12 is open to the left and right sides of the base member 10, the fingers that a worker uses to pinch the electric components 13 do not interfere with the base member 10 if the worker pinches the electric components 13 from the left and right sides. Accordingly, the workability during the attachment of the electric components 13 is good. In addition, in a case in which the electric components 13 are attached using an automatic machine, fingers of the automatic machine do not interfere with the base member 10 if the electric components 13 are held so as to be pinched from the left and right sides using the fingers of the automatic machine.

Next, the pair of side-wall members 11 are attached to the base member 10. The attachment is carried out by: fitting the front-side insertion portions 16 into the groove portions 34 in the front-side fitting portions 14 such that the front-side insertion portions 16 are inserted from above into the groove portions 34; fitting the rear-side insertion portions 17 into the guide grooves 27 in the rear-side fitting portions 15 such that the rear-side insertion portions 17 are inserted from above into the guide grooves 27; and fitting the guide rails 47 of the housing recesses 46 and the guide ribs 24 of the projections 22 to one another and sliding the guide rails 47 and the guide ribs 24 against one another. When the side-wall members 11 have been attached to the base member 10, the component housing chamber 12 is covered from the left and right sides by the side-wall members 11, and the assembly of the electrical junction box A is complete. The component housing chamber 12 is surrounded over the entire circumference thereof, from the front-rear and left-right directions.

In a state in which the side-wall members 11 have been attached to the base member 10, the side-wall members 11 are restricted from separating upward from the base member 10 by the lock portions 43 being locked to the lock holes 28. The side-wall members 11 and the base member 10 are positioned in the front-rear and left-right directions by the front-side insertion portions 16 and the front-side fitting portions 14 fitting to one another. The connection plate portion 53 of each busbar 50 is placed on the upper surface of the plate-shaped mounting portion 38 of a plate 36. Bolts 66 are each inserted through a through-hole 56, mounting hole 39, and bolt hole 33, and are screwed and fastened into nuts 67 provided on the lower surfaces of the receiving plate portions 32. By fastening being performed in such a manner, the plates 36 and the busbars 50 are fixed to the terminal block 30.

In the state in which the side-wall member 11 have been attached to the base member 10, the outer side surfaces of the main body portion 19 are covered by the side-wall members 11. The projections 22 project from parts of the outer side surfaces of the main body portion 19. Due to this, if surfaces facing the main body portion 19 in the outer surfaces of the side-wall members 11 come into contact with the projecting end surfaces of the projections 22, the width dimension of the electrical junction box A would increase by an amount corresponding to the projecting dimensions of the projections 22. In this regard, however, because the projections 22 are housed inside the housing recesses 46 in the side-wall members 11 in the present embodiment, the width dimension of the electrical junction box A does not increase due to the presence of the projections 22, even when the projections 22 are formed.

The housing recesses 46 pass through the inner wall portions 42 to the busbar housing chambers 44 inside the side-wall members 11 from the surfaces facing the main body portion 19 in the outer surfaces of the side-wall members 11. The projections 22 are housed within the ranges of the thicknesses of the inner wall portions 42. Accordingly, compared to a case in which the housing recesses 46 do not pass through the inner wall portions 42 to the busbar housing chambers 44, the width dimension of the electrical junction box A is suppressed to be small. The projections 22 do not interfere with the heat-dissipating plate portions 52 of the busbars 50 because the projecting ends of the projections 22 are positioned, in the width direction, at the same positions as the inner surfaces of the inner wall portions 42 or on the outer-surface side from the inner surfaces of the inner wall portions 42.

The guide ribs 24 of the projections 22 are locked to the guide rails 47 of the housing recesses 46 from the opposite sides from the busbar housing chambers 44 in the width direction. The hook portions 26 of the extending portions 25 are also locked to the lower end edges of the inner wall portions 42 from the opposite sides from the busbar housing chambers 44 in the width direction. By the locking action of such members, the side-wall members 11 are restricted from separating from the base member 10 in the width direction. Thus, even if the side-wall members 11 are urged to undergo thermal deformation in directions away from the base member 10 due to an increase in ambient temperature, etc., the deformation can be prevented. Accordingly, an increase in the size of the electrical junction box A in the width direction can be prevented.

As illustrated in FIG. 4, a pair of left and right heat-dissipation spaces 65 are formed between the base member 10 and the side-wall members 11. The heat-dissipation spaces 65 are spaces that have a left-right dimension smaller than the vertical dimension and the longitudinal dimension. The lower ends of the heat-dissipation spaces 65 are open in the lower end surface of the main body portion 19 of the holding member 18. The upper ends of the heat-dissipation spaces 65 are in communication with the component housing chamber 12. A busbar housing chamber 44 and a heat-dissipation space 65 are in communication with one another via a space between the upper end of a housing recess 46 and the upper end of a projection 22.

An upward air flow is generated inside each heat-dissipation space 65 as a result of outside air having relatively low temperature flowing in from the openings in the lower end surface of the main body portion 19 due to the temperature difference between the outside and inside of the main body portion 19. When the temperature in a busbar housing chamber 44 increases due to a busbar 50 generating heat by being energized, the air flow inside the heat-dissipation space 65 draws heat inside the busbar housing chamber 44 from the gap between a housing recess 46 and a projection 22 and flows into the component housing chamber 12 to be discharged to the atmosphere from openings in the upper surface of the main body portion 19.

### Operation and Effect of Embodiment

The electrical junction box A according to the present embodiment includes: a base member 10 to which electric components 13 are to be attached; and a pair of side-wall members 11 that are attached to the base member 10 so as to sandwich the base member 10 in a width direction. A component housing chamber 12 for housing the electric components 13 is formed by the base member 10 and the pair of side-wall members 11. The base member 10 includes projections 22 that project toward the width direction from outer side surfaces of the base member 10. The side-wall members 11 have formed therein housing recesses 46 for housing the projections 22. According to this configuration, size can be reduced because the width dimension decreases by an amount corresponding to the projecting dimensions of the projections 22 as a result of the projections 22 being housed inside the housing recesses 46.

Busbars 50 are housed inside the side-wall members 11. In a state in which the base member 10 and the side-wall members 11 are separated from one another, the housing recesses 46 are open so as to expose parts of the busbars 50. According to this configuration, size can be reduced in the width direction because there are no partition walls between the projections 22 and the busbars 50. The busbars 50 each include a substrate portion 51 and a heat-dissipating plate portion 52 that is disposed so as to overlap the substrate portion 51. The heat-dissipating plate portions 52 are disposed so as to face the housing recesses 46. Because heat-dissipation spaces 65 are formed between the base member 10 and the side-wall members 11, heat from the heat-dissipating plate portions 52 can be discharged to the heat-dissipation spaces 65 via the housing recesses 46.

The base member 10 has provided therein hook portions 26 and guide ribs 24 as separation-restricting portions that restrict the side-wall members 11 from separating from the base member 10 in the width direction. Even if the side-wall members 11 are urged to undergo bending deformation so as to separate from the base member 10, the bending deformation of the side-wall members 11 is prevented by the hook portions 26 catching on inner wall portions 42 and the guide ribs 24 catching on guide rails 47. Thus, an increase in width dimension due to the deformation of the side-wall members 11 can be prevented.

The outer surfaces of the side-wall members 11 include outermost regions 58 that are farthest from the base member 10 in the width direction. The hook portions 26 and the guide ribs 24, which are separation-restricting portions, are disposed only in regions that are closer to the base member 10 than the outermost regions 58 are. Accordingly, an increase in width dimension of the electrical junction box A due to the presence of the hook portions 26 and the guide ribs 24 can be prevented.

### Other Embodiments

The present invention is not limited to the embodiment described based on the drawings and the description above, and, rather, is indicated by the claims. The present invention includes all modifications that are included in the claims and that are within the meaning and scope of equivalents of the claims, and is intended to also include the following embodiments.

In the above-described embodiment, the housing recesses are in communication with the inside of the busbar housing chambers; however, the housing recesses need not be in communication with the inside of the busbar housing chambers.

In the above-described embodiment, the heat-dissipating plate portions face the housing recesses; however, the heat-dissipating plate portions may be disposed at positions not facing the housing recesses.

In the above-described embodiment, separation-restricting portions are provided in the base member; however, the base member need not include separation-restricting portions.

In the above-described embodiment, heat-dissipation spaces are formed between the base member and the side-wall members; however, heat-dissipation spaces need not be formed between the base member and the side-wall members.

### LIST OF REFERENCE NUMERALS

A Electrical junction box
10 Base member
11 Side-wall member
12 Component housing chamber
13 Electric component
14 Front-side fitting portion
15 Rear-side fitting portion
16 Front-side insertion portion
17 Rear-side insertion portion
18 Holding member
19 Main body portion
20 Front plate portion
21 Rear plate portion
22 Projection
23 Outermost-position cavity
24 Guide rib (separation-restricting portion)
25 Extending portion
26 Hook portion (separation-restricting portion)
27 Guide groove
28 Lock hole
30 Terminal block
31 Supporting plate portion
32 Receiving plate portion
33 Bolt hole
34 Groove portion
35 Housing space
36 Plate
37 Plate-shaped power supply portion
38 Plate-shaped mounting portion
39 Mounting hole
40 Side-wall main body
41 Outer wall portion
42 Inner wall portion
43 Lock portion
44 Busbar housing chamber
45 Busbar attachment port
46 Housing recess
47 Guide rail
50 Busbar
51 Substrate portion
52 Heat-dissipating plate portion
53 Connection plate portion
54 Tab
55 Supporting portion
56 Through-hole
57 Enlarged-width portion
58 Outermost region
59 Fuse housing chamber
60 Fuse
61 Lead
65 Heat-dissipation space
66 Bolt
67 Nut

1. An electrical junction box comprising:
a base member to which electric components are to be attached; and
a pair of side-wall members that are attached to the base member so as to sandwich the base member in a width direction,
wherein a component housing chamber for housing the electric components is formed by the base member and the pair of side-wall members,
the base member includes projections that project toward the width direction from outer side surfaces of the base member, and
the side-wall members have formed therein housing recesses for housing the projections.

2. The electrical junction box according to claim 1,
wherein busbars are housed inside the side-wall members, and
in a state in which the base member and the side-wall members are separated from one another, the housing recesses are open so as to expose parts of the busbars.

3. The electrical junction box according to claim 2,
wherein the busbars each include a substrate portion and a heat-dissipating plate portion that is disposed so as to overlap the substrate portion,
the heat-dissipating plate portions are disposed so as to face the housing recesses, and
heat-dissipation spaces are formed between the base member and the side-wall members.

4. The electrical junction box according to claim 1, wherein the base member has provided therein separation-restricting portions that restrict the side-wall members from separating from the base member in the width direction.

5. The electrical junction box according to claim 4,
wherein the outer surfaces of the side-wall members include outermost regions that are farthest from the base member in the width direction, and
the separation-restricting portions are disposed only in regions that are closer to the base member than the outermost regions are.
